(19) United States
(12) Patent Application Publication
(10) Pub. No.: US 2009/0141905 A1
(43) Pub. Date: Jun. 4, 2009

(54) NAVIGABLE AUDIO-BASED VIRTUAL ENVIRONMENT

(76) Inventor: David Warhol, Manhattan Beach, CA (US)

Correspondence Address: SONNABENDLAW, 600 PROSPECT AVE, BROOKLYN, NY, 11215, US

(21) Appl. No.: 11/949,213

(22) Filed: Dec. 3, 2007

(51) Int. Cl. H03G 3/00; A63F 9/24

(52) U.S. Cl. 381/61; 463/35

(57) ABSTRACT

The invention is directed to a sound system for providing an audio-based virtual environment, wherein the sound system includes: (a) a device-readable medium having stored thereon a device-readable code for encoding the audio-based virtual environment; (b) a sound-transmitting device capable of stereophonic output to a listener navigating within the audio-based virtual environment; and (c) a suitable interface capable of providing a listener with means to select a direction for navigating within the audio-based virtual environment.

### BACKGROUND OF THE INVENTION

I. Field of the Invention

The present invention relates generally to the field of sound systems, and more specifically to sound systems involving virtual audio environments.

II. Background of the Related Art

Computer gaming products remain one of the most popular and profitable of consumer recreational goods. More recently, computer-generated virtual environments (i.e., virtual worlds) have also greatly increased in popularity. These virtual environments typically either simulate a real-world environment or create a fictitious environment by extensive use of visual-based, graphical tools. While a computer game generally limits a user to playing a game using prescribed rules, a virtual environment can also be non-competitively recreational, informative, or instructional.

Also highly popular among recreational items are the recent digital audio players, such as the Apple iPod Nano by Apple, Inc., which are conveniently mobile hand-held devices that can store, organize, and play digital music files. They commonly include a feature by which new and updated music files can be readily downloaded from the internet or a computer.

Though both computer-generated virtual environments and audio-based recreational systems remain independently highly popular, no product is known in which a virtual environment is constructed by sole use of audio-based effects. More particularly, the inventor is not aware of such an audio-based virtual environment which allows a listener to navigate and interact therein while experiencing sound effects as they would realistically appear to a traveler in real space. Some of the effects experienced by a traveler in real space include dynamic sound changes due to changes in distance and orientation of a sound-producing object with respect to the traveler, as well as changing sounds caused by changes in the virtual environment or game state.

U.S. Published Application 2004/0037434 discloses a method and apparatus of providing a user with a spatial metaphor to allow a user the ability to better visualize and navigate an application. The invention requires a background audio prompt and a foreground audio prompt to indicate the alternatives available to the user. Though the disclosed invention is directed to audio-based effects for providing a spatial metaphor, the application does not disclose a real-world simulated virtual environment in which sound effects realistically and dynamically change based on the moment-by-moment change in position of sound-producing objects with respect to the listener within the virtual space, nor does it disclose any changes to audio-based on objects states of various objects of the virtual environment.

U.S. Published Application 2003/0095669 discloses an audio user interface in which items are represented in an audio field. The application does not disclose an audio-based virtual environment in which a listener can navigate and experience sound effects as they would appear dynamically in real space.

There remains an uncharted realm for audio-based systems in which a user can enjoy navigating within a realistically-simulated virtual world constructed solely of sound elements. The prior art also is devoid of any teaching of audio-based systems that include state-based audio derived from object states for objects contained in a virtual world.

### SUMMARY OF THE INVENTION

As a result of the present invention, there is provided a new and useful interactive environment based solely on sound effects and which can be used for recreational, informative, or instructional purposes. The invention provides the additional benefits of appealing to those who are more audio-inclined as opposed to visual-inclined, and in addition, to those suffering from visual impairment. Therefore, a beneficial result of this invention is to provide for those who are more audio-inclined or who suffer from a visual impairment an ability to enjoy a computer-generated virtual environment.

These and other aspects of the subject invention will become more readily apparent to those having ordinary skill in the art from the following detailed description of the invention.

### BRIEF DESCRIPTION OF THE DRAWINGS

So that those having ordinary skill in the art to which the subject invention pertains will more readily understand how to make and use the subject invention, preferred embodiments thereof will be described in detail herein with reference to the drawings.

FIG. 1 is schematic diagram of a preferred embodiment of the present invention.

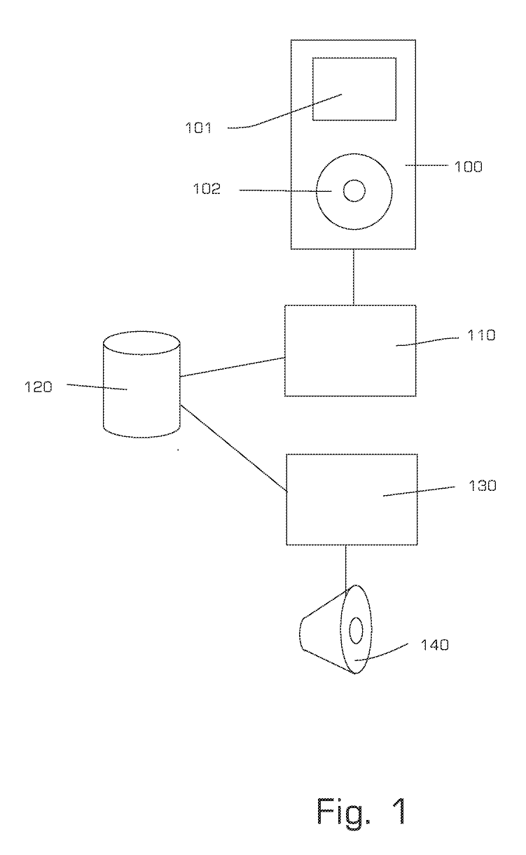

### DETAILED DESCRIPTION OF THE PREFERRED EMBODIMENTS

The present invention relates to an audio-based virtual environment.

As used herein, the term “virtual environment,” also known as a “virtual world,” describes a virtual space in which a user can navigate by various modes to come in virtual contact with objects in the environment. A “virtual space” is a wholly or partially immersive simulated environment, as contrasted with a “real space,” which refers to the space or environment that people experience in the real world.

As used herein, “audio-based virtual environment,” “audio-based virtual world,” and “audio-based virtual space” mean a virtual environment actualized exclusively by sound effects (defined below) and without use of graphical depictions of such virtual environment.

As used herein, “state” means the condition of a person, thing or environment as with respect to circumstances or attributes of such person, thing or environment; or the condition of matter with respect to structure, form, constitution, phase, or the like; or the complete pertinent set of properties of a person, thing or environment. “Game state”, as use herein, may include the overall state of the virtual environment, and may include the state of any or all users and objects contained within the virtual environment.

The term “sound effects” as used herein includes any desired sound, or combination or modification of sounds, including, for example, sounds from inanimate or natural objects, creatures, characters, musical pieces or notes, voices, tones, abstract sounds, and combinations thereof.

One preferred embodiment discloses a device-readable medium having stored thereon a device-readable code defining an audio-based virtual environment, the device-readable code having code defining at least one location for sound effects within a virtual space; code for providing a listener of the sound effects an ability to navigate in real time within the audio-based virtual environment by providing input to an interface; and code for generating the sound effects relative to a listener position within the virtual space.

Another preferred embodiment discloses a sound system for providing an audio-based virtual environment, the system having a device-readable medium, 120, having stored thereon device-readable code for defining an audio-based virtual environment; an audio generator, 130, operatively connected to the device-readable medium for creating audio-based on the device-readable code; a controller, 110, operatively connected to the device-readable medium for controlling a rendering of the audio-based environment; and an interface, 100 operatively connected to the controller providing user interaction with the audio-based virtual environment wherein the controller transmits control signals to the device-readable medium and the device-readable medium transmits signals to the audio generator in response to the signals from the controller. The interface may include a display, 101, and an input means such as jog wheel/buttons 102. Transducer 140 may be operatively coupled to audio generator 130 for transmitting sounds generated by audio generator 130.

The control signals may be any electrically or optically encoded instructions in any protocol understood by the device-readable medium. The signals to the audio generator may be any encoded signal representing audio, for example, PCM encoded signals, understood by the audio generator.

The embedded objects found in a virtual space may include, for example, inanimate objects, nature-based creatures and objects, fictitious characters, or other players. A virtual world typically encodes the various objects so that they move and function in a manner consistent with the way true objects would behave, appear, or function in real space. In other words, a virtual environment typically simulates, by some degree, the properties of objects in the real world. Embedded objects may exhibit states or inherent attributes which may be rendered (that is, created) by sounds generated in the audio-based virtual environment.

All of the currently known virtual worlds rely in substantial part on graphic depictions of the virtual environment. They can function as either an exploratory environments or a gaming environments. Some examples of currently known virtual worlds include Active Worlds (www.activeworlds.com) by Active Worlds Corporation, ViOS (www.vios.com) by ViOS, Inc., There (www.there.com) by Makena Technologies, Second Life (www.secondlife.com) by Linden Research, Inc., Entropia Universe (www.entropiauniverse.com) by MindArk, The Sims Online (www.thesimsonline.com) by Maxis, Red Light Center (www.redlightcenter.com) by Utherverse, Inc., and Kaneva (www.kaneva.com) by Kaneva, Inc. It has become increasingly popular for virtual environments to include multiple interactive players who are able to communicate with each other.

In contrast to the virtual environments known in the art, embodiments of the present invention provide a virtual environment that is strictly audio-based (except for visual navigational elements in certain embodiments, as discussed in further detail below). All encoded sound sources, such as inanimate or natural objects, natural or fictitious creatures, characters, conditions (e.g., wind, rain, water, fire) are rendered by or as sound effects.

The audio-based virtual environment described herein may be constructed and defined according to a device-readable computer program, also known as a “computer code,” “program,” or “code.” Since the virtual space may include only sound effects, the code for the audio-based virtual environment may exclude code for graphical objects. The code herein may be additionally encoded to function in the absence of a visual-based virtual environment. As used herein, the coding involved in producing the sound elements, along with their combined and modified forms, is generally known in the art.

The audio-based virtual environment described herein may be transmitted to a listener by means of a sound system. The sound system may include (i) a device-readable medium having stored thereon a device-readable computer code which encodes and defines the audio-based virtual environment, (ii) an audio generator capable of receiving sound-generating instructions from the device-readable code and transmitting these to a listener navigating within the audio-based virtual environment; and (iii) a suitable interface capable of providing a listener with means to select a direction for navigating within the audio-based virtual environment.

The code may include a set of spatial coordinates within which encoded sound elements are placed at specific locations. The computer coding required to produce a virtual spatial grid of any dimension (e.g., a two- or three-dimensional space), as well as the methods for embedding objects in specific locations therein, is well-known in the art.

The code may be stored on a device-readable medium in order that the code can be accessed and executed by the sound system to provide the encoded audio-based virtual environment to a user. The device-readable medium may be currently known or later developed medium for storing computer, microprocessor or other controller instructions and data, and may include appropriate hardware and firmware for reading and or writing such instructions and data in a sequential and/or non-sequential/addressable manner. The device-readable medium may include any appropriate electronic, photonic, or magneto-optical storage technology known in the art. Some examples of such media include, for example, the floppy diskette, hard drive, compact disc (e.g., CD-ROM, CD-R, CD-RW, mini-CD, CD-Audio, Red Book Audio CD, Super Audio CD), digital versatile disc (e.g., DVD-R, DVD-ROM, DVD-RAM, DVD-RW, DVD-Audio, mini-DVD), flash drive, and memory card.

A controller may be used to retrieve data comprising audio for the audio-based virtual environment from the device-readable medium. Such controllers, in the form of a computer, microprocessor or other controller, are well known in the art.

The sound system that accesses and executes the code may include an audio generator capable of generating stereophonic output to a listener navigating within the audio-based virtual environment. As used herein, “stereo,” “stereophonic” and like terms will be understood to mean audio output of two or more spatially distinct channels. The sound-transmitting device may receive an input signal from a audio generator, the audio generator being capable of converting the input it receives into an analog signal capable of audible reproduction by a transducer.

The present invention may also include two or more transducers such as headphones (i.e., stereophones), speakers, and surround sound systems. The transducers may be any of the known devices in the art, including, for example, dynamic (electrodynamic) drivers, electrostatic drivers, balanced armature drivers, and orthodynamic drivers.

Particularly preferred for the present invention are headphones. The headphones may be of the currently popular variety used commonly in digital audio players, or may be more specialized to include, for example, the circumaural, supra-aural, earbud, or canal phone (interruptive foldback system, IFB) types of headphones. The headphones may be designed to be positioned in any suitable manner onto or in proximity of the listener, including over the head, behind the head, clipped onto the pinnae (outer ear), or in the ear. The headphones may include any suitable sound-generating element, such as small loudspeakers or an audio amplifier device. Such audio amplifier devices are often integrated with other elements as part of an integrated amplifier.

Only audio output of two or more spatially distinct channels, when instructed by suitable audio signal-processing techniques encoded within the device-readable code, may provide the illusion to a listener of a sound-producing object being in location or orientation different from the listener. The signal-processing techniques may include a variety of processing methods, as known in the art, for modifying sounds to provide such an illusion. Some of the signal-processing means include modifying the amplitude, frequency, and/or higher harmonic component of sounds.

The audio signal-processing techniques referred to are those known in the art which make use of two or more spatially distinct channels for creating the illusion of a sound emanating from a particular location or a particular orientation with respect to the listener. The sound effects may be made to appear to have a static or changing distance from, or a static or changing orientation to, the listener. For example, signal-processing techniques may be used to create the impression of a sound source positioned to the right or left, in front or behind, or above or below, a listener.

The audio signal-processing techniques may make a sound object appear to change in position as the virtual position of either the listener or object, or both, change. A change in position of a sound object may include, for example, a change in distance between the sound object and the listener, or a change in orientation between the sound object and listener, or both. Each type of change in position may occur independently by movement of the sound object, or the listener, or both. In the case of simulating a changing distance between the sound object and listener, the signal-processing techniques are capable of providing the illusion of a sound object approaching or receding axially relative to a stationary listener (and vice-versa, an approaching or receding listener axially relative to a stationary sound object). In the case of a change in orientation, the signal-processing techniques are capable of providing the illusion of a sound object changing position angularly in either two dimensions or three dimensions with respect to the listener.

For example, the signal-processing techniques may make it possible for a sound object appearing to the left of a listener to move with or without a change in distance to the listener in a sweeping arc 90 degrees to the front of the listener and then another 90 degrees in a sweeping arc to the right of the listener. Alternatively, the position of the listener could have changed while the sound object appeared unmoved to achieve the same result. The signal-processing techniques may also allow that the sound output of a sound object be dynamically and continuously modified during a motion sequence to properly simulate the sound emanating from an object varying in position to a listener as it would appear to a listener in the real world.

The sound system may also include an interface capable of providing the listener with means to select a direction for traveling within the virtual space or for interacting with the virtual space (i.e., an input to the interface allows the listener to select a direction for traveling or for otherwise interacting with the virtual space). The interface may be any suitable interface that permits a user to select a direction for navigating within the audio-based virtual environment or to interact with the virtual space. The navigating tool within the interface may be designed to allow the listener to travel within any prescribed set of coordinates, most typically in either a two-dimensional or three-dimensional set of coordinates within the virtual space, or to otherwise interact with the virtual space.

The navigating tool on the interface may be, for example, a keypad containing directional elements. The directional elements in the keypad may be provided, for example, in the form of depressable keys or buttons, a pressure pad, a chiclet pad, a display screen keypad, or a touch screen. The keypad may provide any number of suitable directional elements, such as, for example, left and right only, forward and backward only, left, right, forward, and backward only, or left, right, forward, backward, up and down only, and so on. The keypad may designate the directional elements in any suitable format, including, for example, as directional elements referenced to the user (e.g., left, right, forward, or backward, or a series of 1 to 9 directions, among others), or directional elements referenced to the virtual environment (e.g., north, south, east, and west, and combinations thereof).

The navigating tool may also be in the form of a joystick, mouse, trackball, or scroll wheel. These navigating tools typically allow the user to navigate in a freely-determined manner without being confined to selecting a specific direction at any given moment.

The navigating tool may also be included in a visual display screen of the interface. In this embodiment, the prompts that provide directional information are preferably limited to simple language-phrase information, single words, or simple cues or symbols (e.g., arrows). For example, the display screen may show a series of arrows pointing in various directions for the listener to select, or may provide such words or phrases as “this way east,” or “press the up arrow to go north” or “press the S key to go south,” and so on.

The navigating tool may also be provided by the interface in the form of a voice-recognition element. For example, the navigator may vocalize a word or phrase into the interface, which then functions as a command to the sound system for navigating in the direction selected by the user.

The invention also provides for the use of any of a variety of directional navigational modes. For example, a direction may be selected by pressing a navigation tool once, or alternatively, by pressing and holding a navigation tool for a specified duration or the entire duration in which movement in a direction is desired. In an embodiment where a navigation tool is required to remain activated (e.g., pressed) for the duration of a movement, it may also be provided that releasing the navigation tool stops the movement. Similarly, navigation may be accomplished by effecting inputs, including, for example, key presses, timed relative to certain audio events generated by the system and presented integrally to the virtual environment.

Navigation through the virtual space may be effected in “real time”, that is, with appropriate feedback such as audio feedback being provided sufficiently quickly and without substantial delays or pauses so as to simulate the experience the same user would have in the real world. In other embodiments, navigation may be effected in “contracted time”, that is, where navigation is effected wholly or partially in temporal jumps from a starting location to an ending location without the perception of traveling through points between the two locations. Navigation through the virtual space may also be effected by a combination of real time and contracted time navigation.

In other embodiments, the user is required to interact with a navigation tool more than once in succession to activate additional capabilities. For example, it may be provided that a key be pressed two, three, or more times to activate a variable speed function, wherein, for example, pressing two times in a certain direction corresponds to a faster rate of movement in a direction compared to pressing once, and pressing three times corresponds to a faster rate of movement in a direction compared to pressing twice.

In other embodiments, navigation may be limited by an encoded condition. For example, a bounding box may be included wherein the user may be restricted from moving into pre-defined areas within the virtual environment. If desired, sound effects may alert the user to the constraint. Or, for example, one or more interaction zones may be included wherein, as a character's position moves to within a pre-defined distance of a point, a game state reaction initiates. Navigation may also be limited by forced motion wherein, based on a game state, the user's position may be continuously or discontinuously moved.

The interface may include narration for informing the user of any of a variety of options, such as directional options for movement, options for interacting with objects in the virtual environment, and the like. The narration may also provide the user with game state information. Any of the interface embodiments discussed herein may be implemented in whole or in part via narration.

The narration may also provide a listener with more detailed stat or directional information, such as where the user is currently located, where the user is headed, the different possible actions the user may take, directions the user may travel, hints for achieving a goal, or the current state of the user. For example, the narration may provide such words or phrases as “north,” or “heading north,” or “going southeastward,” or “you are at home,” or “approaching the west entrance,” and so on. The narration may be more detailed, such as, for example, “You are in the coffee shop. If you go forward, you will order a cup of coffee; by turning right, you will enter the street” or “you have hit a wall and need to choose another direction” or “you are not allowed to enter this zone.”

For further example, the narrated navigational mode may include, a deliberate compass direction, a user-driven menu, timed multiple choice, key sequences and patterns, action-response-to-game-stimulus, state-supplied solution, state-forced motion, time-out forced motion, and puzzle. Any suitable interactive means, as described above, may be used by a listener when interacting within a narrated navigational mode (e.g., tactile pressing of keys or use of a touchscreen, voice recognition, or screen tools, such as a mouse, joystick, scroll wheel, or trackball).

The narration may be specifically suited for game playing as well. For example, in a game-based virtual environment of the present invention, a voice prompt may state “you are out of energy and need to collect more points” or “you may only enter this zone after you have found the key.”

The virtual environment likewise may use intuitive sounds to communicate game play conditions or environmental states, e.g., by producing a “grunting” sound spatially located at the player's position when the player attempts to open a door requiring a key.

Preferably, the interface may also include means for the user to change his or her perspective in the virtual world. Changing perspective is distinct from navigating or selecting a direction in that the perspective refers only to how the virtual world is being presented to the user. For example, a change in perspective may include changing the zoom factor (e.g., from panoramic to close-in), the angle, or the environment itself. The means for changing perspective may include means for selecting, adjusting, modifying, and/or changing a perspective within the audio-based virtual environment. It will be understood that changes in perspective thus described are not meant to indicate visual perspectives but sound-based perspectives.

Preferred embodiments of the present invention may include one or more directional options to be offered to the user. The directions may be compass points, such as north, south, east, west, northeast, northwest, southwest, and southeast, and may also include up and down. The directions may also be described as forward, backward, right, left, and similar relative directions. Each direction may map to a corresponding direction on the input device. Another option may be possible by using a selection, shift, control or similar button in addition to a direction of the input device. When the user selects a direction, he or she is brought to a new location corresponding to that direction. Not all directions need be active at a time. As previously discussed, the directional options may be offered via narration (e.g., “Looks like I can go north into the coffee shop or south back onto the street”) or may be offered via sound effect cues (e.g., the user hears the sound effect of a rabbit run to the right, and presses right. Once there, the user hears the sound of the rabbit run ahead of him, and then presses forward.)

Preferred embodiments of the present invention may include a user-driven menu mode giving a user an ability to cycle through a series of choices under the user's direct control. In this mode, pressing one direction on the input device may cycle the user forward through the series, and another button cycles the user backward through the series. When the user encounters the desired option, the user may press a selection button to activate that option, and the user may then be taken to that location. The series may be of any length, may or may not cycle from the end to the beginning, and may or may not be traversable in both forward and backward directions. The series may be offered via narration (e.g., “Let me buy a ticket. Tripoli. (press) Istanbul. (press) London. (press) Paris. (backward press) London. (press) Paris. (press) Rio de Janeiro.”) or via sound effects (e.g., the player hears a series of animals, one of which he selects to ride). Besides being useful for ambulation to a different location, user-driven menus may also change the game state.

A timed multiple choice mode may include a sequence of phrases or sounds played for a user from one or more locations. The sequence may be randomized and/or may cycle in series. The user makes a selection during the desired phrase or sound, and the action of doing so may take the user to another location based on a selected choice. The sequence may be offered via narration (e.g., “Maybe I will get in the red boat. Or I could take the blue car. Or the yellow rickshaw”), or the sequence may be offered via sound effect cues (e.g., the user listens to the sounds of multiple taxis passing by, each of which has a different sound, and makes a selection when he hears the sound of the taxi he wants to take). Besides being used for ambulation to a different location, timed multiple choice sequences may also change the game state. Game state changes may be conveyed via narration (e.g., “I'll get some ice cream. How about chocolate. Vanilla looks great. Strawberry is my favorite.”) or through sound effects (e.g., the user is presented a box of squeeze toys; each squeeze toy plays in sequence; the user presses the selection button to indicate which squeeze toy he wants to pick up), or through a combination of both narration and sound effects.

The key sequences and patterns mode may include the ability for a player to enter a series of keystrokes to match a pattern. If the pattern is successfully replicated via user input, the user is moved to a new location. The pattern may contain different keystrokes, and may require keystrokes being entered in specific timed intervals. The sequence may be offered via narration (e.g., “Click your heels together three times to go home”) or via sound effects (e.g., the player taps out a secret knock, “shave-and-a-haircut, two bits” on a door to gain entry), or a combination of narration and sound effects. Besides being used for ambulation to a different location, the key sequences and patterns mode may also change the game state. Game state changes may be conveyed via narration (e.g., “Turn the combination lock left three times, then right four times, then open the safe.”) or through sound effects (e.g., honking on a horn in a certain pattern is a signal to have someone enter the user's car).

The action-response-to-game-stimulus mode may present to players a sound effect to which players must react within a set period of time to that sound effect with a deterministic input response. For example, the user may hear a gunshot to the left, and be required to “dodge” immediately by making an appropriate selection to move evasively to a safe location. Besides being used for ambulation to a different location, action response to game stimulus may also change the game state. For example, the user may hear a fly buzzing around in an annoying manner. When the fly stops, the user may respond by pressing the user input in the appropriate direction of where the fly was when it stopped in order to “swat” the fly, thereby eliminating the game state of a buzzing fly.

The state-supplied (or state-based) solution mode may include sound effects (i.e., behavior, action, or responses of sound objects) that depend on the state of one or more conditions within the audio-based virtual environment. For example, in one embodiment, a passage to one location may be obstructed until the user either visits or changes a game state at another location. For example, upon arriving at a location, a user may arrive at a locked door. If the user arrives at the locked door without a key to the door, this mode may prohibit the user from proceeding past the locked door. Once the user has visited the location containing the key, the user may proceed through the door to a new location. As another example, a previously closed window, after being opened, might allow sounds from the outside to be heard. As yet another example, after a “blackout,” electrically-operated equipment could become quieted. In each of these examples, the game states may be conveyed to players by one or more sound effects depicting and corresponding to the game state, through narration, or both.

A state-supplied solution mode may also act upon another narrated navigational mode. For example, at a specific location, the user may only be given two compass directions in which he may move; however, if the player visits a third location or changes a game state, when he returns to the location he may instead be given three compass directions in which to move.

The state-forced motion mode may provide events out of the control of the user which force the user to a new location. For example, getting struck by an automobile may require that the user proceed to a virtual hospital, or falling through a crevasse may require that the user wait for a period of time in an underground cavern.

The time-out-forced motion mode may provide a game state transition whereby a user who does not actively interact with the input mechanism and make a selection within a predetermined timeout period may be forced into a new location or other game state change. For example, if the user is prompted to select one of three characters to fight, and the user does not make a selection in the required time period, the user may be forced to work as a blacksmith instead of a knight or be demoted to a lower level character with less fighting ability.

The puzzle mode may provide user with audio-based puzzle which a user may solve by discerning different sounds that correspond to different objects. For example, a goal may be for a user to select a correct crystal among several crystals having different sounds based on an earlier or current audio clue. Or, for example, the goal may be for a user to recognize a specific sequence of sounds. Another example is wherein the user may be required to construct different combinations of sounds to find a combination that causes a desired result (e.g., finding a correct combination of sounds may unlock a secret entranceway). The puzzle mode may work in combination with any of the other modes described above. For example, if a user does not solve the puzzle within a certain time or within prescribed rules, the user may be forced to a new location or experience another game state change.

In a preferred embodiment, the sound system is a digital audio player. A digital audio player is a device which typically includes the ability to store, organize and play digital audio files. These devices are commonly be referred to as MP3 players.

In one embodiment, the digital audio player is a flash-based player. A flash-based player uses solid-state devices to hold digital audio files on internal or external media, such as memory cards. These devices may typically store in the range of 128 MB to 8 GB of files. Their capacity may usually be extended with additional memory. An example of a well-known flash-based audio player is the Apple iPod Nano by Apple, Inc. As they typically do not use moving parts, they tend to be highly resilient. These players are very often integrated into a flash memory data storage device (flash drive device), such as a USB flash drive or USB keydrive device.

In another embodiment, the digital audio player is a hard drive-based player, also known as a digital jukebox. These types of devices read audio files from a hard drive and generally have a higher storage capacity ranging from about 1.5 GB to 100 GB, depending on the hard drive technology. At typical encoding rates, this corresponds to the storage of thousands of audio files in one player. The Apple iPod by Apple, Inc. and Creative Zen by Creative Technology Ltd. are examples of popular digital jukeboxes.

The sound system may further include a coupling interface with means for enabling the transmission of audio files contained on a computer into the device-readable medium of the sound system. As used herein, the term “computer” refers to any device or system capable of storing computer files, such as a personal computer, a server on the internet, a laptop or other portable device, from which audio files may be downloaded and imported into the sound system of the present invention. The process of transmitting such files from a computer into a device is more commonly referred to as “downloading” the files from the computer into the device. The files may also be considered to be “imported” into the device from the computer.

Any suitable coupling interface for downloading from another computer or device may be used. More commonly, the coupling interface is a USB interface. Often, the coupling interface is a component of a flash memory data storage device.

The sound system of the present invention may include any additional components that may serve to enhance or modify aspects of the sound system, except that these additional components do not include means for introducing graphical depictions of the virtual environment. For example, the sound system may also include, or be contained within, a flash memory data storage device. The sound system, particularly in the case of a digital audio player, may also include a memory card. The memory card may be either permanently integrated or detachable. The memory card may be of any suitable technology, including a solid state or non-solid state memory card. The sound system may also include the ability for podcasting, wherein radio-like programs are automatically downloaded into the device and played at the user's convenience.

While the present invention is illustrated with particular embodiments, it is not intended that the scope of the invention be limited to the specific and preferred embodiments illustrated and described.

What is claimed is:

1. A device-readable medium having stored thereon device-readable code, the device-readable code comprising:
(i) code defining an audio-based virtual environment having at least one location for sound effects within said virtual environment;
(ii) code for providing a listener of said sound effects an ability to navigate within said audio-based virtual environment by providing input to an interface; and
(iii) code for generating said sound effects relative to a listener position within said virtual environment.

2. The device-readable medium of claim 1, wherein each of said at least one location for sound effects corresponds an object embedded in said audio-based virtual environment in said virtual environment.

3. The device-readable medium of claim 2, wherein said at least one object embedded in said virtual environment has multiple states and said code for generating sound effects includes code for generating sounds based on said states.

4. The device-readable medium of claim 1 further comprising:
code for allowing user interaction with said virtual environment; and
code for generating narration, said narration comprising one or more of a directional option for movement within said virtual environment, an option for interacting with objects in said virtual environment and game state information.

5. The device-readable medium of claim 4, wherein each of said at least one location for sound effects corresponds to an object embedded in said audio-based virtual environment in said virtual environment.

6. The device-readable medium of claim 5, wherein said object embedded in said audio-based virtual environment has multiple states and said code for generating sound effects includes code for generating sounds based on said states.

7. The device-readable medium of claim 5, wherein said user interaction comprises interaction with said object embedded in said audio-based virtual environment.

8. The device readable medium of claim 7, wherein said object embedded in said audio-based virtual environment has multiple states and said code for generating sound effects includes code for generating sounds based on said states.

9. The device readable medium of claim 8, wherein said states change based on said user interaction.

10. The device-readable medium of claim 1 wherein each of said at least one location for sound effects corresponds to at least one object embedded in said audio-based virtual environment in said virtual environment and said code for generating said sound effects relative to a listener position within said virtual environment includes code for generating sound effects corresponding to each of said at least one embedded object.

11. The device-readable medium of claim 10 wherein said at least one object embedded in said virtual environment has multiple states and said code for generating sound effects includes code for generating sounds based on said states.

12. The device-readable medium of claim 11 further comprising code for allowing user interaction with said virtual environment; and
code for generating narration, said narration comprising one or more of a directional option for movement within said virtual environment, an option for interacting with objects in said virtual environment and game state information.

13. The device-readable medium of claim 12 wherein each of said at least one location for sound effects corresponds an object embedded in said audio-based virtual environment in said virtual environment.

14. The device-readable medium of claim 13 wherein said object embedded in said audio-based virtual environment has multiple states and said code for generating sound effects includes code for generating sounds based on said states.

15. The device-readable medium of claim 13 wherein said user interaction comprises interaction with said object embedded in said audio-based virtual environment.

16. The device-readable medium of claim 15 wherein said object embedded in said audio-based virtual environment has multiple states and said code for generating sound effects includes code for generating sounds based on said states.

17. The device-readable medium of claim 16 wherein said states change based on said user interaction.

18. A sound system for providing an audio-based virtual environment, the system comprising:
(a) a device-readable medium having stored thereon device-readable code for defining an audio-based virtual environment;
(b) an audio generator operatively connected to said device-readable medium for creating audio signals based on said device-readable code, said audio signals including signals for narration, said narration comprising one or more of a directional option for movement within said virtual environment, an option for interacting with objects in said virtual environment and game state information;
(c) a controller operatively connected to said device-readable medium for controlling a rendering of said audio-based environment; and
(d) an interface operatively connected to said controller providing user interaction with said audio-based virtual environment
wherein said controller transmits control signals to said device-readable medium and said device-readable medium transmits signals to said audio generator in response to said signals from said controller.

19. The sound system according to claim 18, said device readable code further defining at least one object embedded in said audio-based virtual environment.

20. The sound system according to claim 19, wherein said at least one object embedded in said audio-based environment has multiple states and said audio generator generates audio signals based on said states.

21. The sound system according to claim 20, wherein said states change based on said user interaction.

22. The sound system according to claim 18, wherein said interaction comprises user movement through said audio-based virtual environment.

23. The sound system according to claim 18, said device readable code further defining changes in a spatial orientation of said user in said audio-based virtual environment.

24. The sound system according to claim 22, said device readable code further defining at least one object in said audio-based virtual environment.

25. The sound system according to claim 24, wherein said at least one object embedded in said audio-based environment has multiple states and said audio generator generates audio signals based on said states.

26. The sound system according to claim 25, wherein said states change based on said user interaction.

27. The sound system according to claim 23, said device readable code further defining at least one object in said audio-based virtual environment.

28. The sound system according to claim 27, wherein said changes in spatial orientation of said user is relative to a position of said object embedded in said audio-based environment.

29. The sound system according to claim 28, wherein said at least one object embedded in said audio-based environment has multiple states and said audio generator generates audio signals based on said states.

30. The sound system according to claim 29, wherein said states change based on said user interaction.
